(19) United States
(12) Patent Application Publication
(10) Pub. No.: US 2007/0102716 A1
(43) Pub. Date: May 10, 2007

(54) Image sensor and fabricating method thereof

(75) Inventor: Sang Sik Kim, Suwon-city (KR)

Correspondence Address: MCKENNA LONG & ALDRIDGE LLP, 1900 K STREET, NW, WASHINGTON, DC, 20006, US

(73) Assignee: DONGBUANAM SEMICONDUCTOR INC., Seoul (KR)

(21) Appl. No.: 11/320,948

(22) Filed: Dec. 30, 2005

(30) Foreign Application Priority Data
Nov. 10, 2005 (KR) 10-2005-0107683

(51) Int. Cl. H01L 33/00

(52) U.S. Cl. 257/89

(57) ABSTRACT

An image sensor and fabricating method thereof enable total photoelectric conversion without light loss by enhancing surface uniformity of a microlens in each area of the microlens. The method includes the steps of forming a sublayer including a photodiode, a thin film transistor and metal lines on a substrate including a pad area and a cell area, forming a first planarizing layer on the sublayer, forming a plurality of color separating layers on the first planarizing layer within the cell area, forming a second planarizing layer on the first planarizing layer including at least one of the plurality of color separating layers in the cell area, forming a plurality of microlenses on the second planarizing layer to overlap the plurality of color separating layers, respectively, and forming a capping layer on the second planarizing layer to fill gaps between the plurality of microlenses.

This application claims the benefit of Korean Patent Application No. 10-2005-0107683, filed on Nov. 10, 2005, which is hereby incorporated by reference for all purposes as if fully set forth herein.

### BACKGROUND OF THE INVENTION

1. Field of the Invention

The present invention relates to a semiconductor device, and more particularly, to an image sensor and fabricating method thereof. Although the present invention is suitable for a wide scope of applications, it is particularly suitable for enabling total photoelectric conversion without light loss by enhancing surface uniformity of a microlens in each area of the microlens.

2. Discussion of the Related Art

An image sensor is a semiconductor device that converts an optical image to an electric signal. Image sensors may be classified into charge coupled devices (CCD) and CMOS (complementary metal oxide silicon) image sensors.

The image sensor includes a photodiode unit that senses an applied light and a logic circuit unit that processes the sensed light into data via electric signals. The photosensitivity of the image sensor increases as the photodiode unit receives more light.

To enhance photosensitivity, the fill factor, which is a ratio of a photodiode area over a total area of an image sensor, may be increased. Also, to enhance photosensitivity, a path of light incident on an area excluding a photodiode is diverted to be condensed onto the photodiode.

A microlens may be used to condense light onto the photodiode. An increased quantity of light can be applied to a photodiode area by refracting a path of incident light using a convex microlens over the photodiode. The microlens is made of a substance having a good transmittance.

Light parallel to an optical axis of the microlens is refracted by the microlens to have a focus at a prescribed position on the optical axis.

CMOS image sensors may be classified into a 3T type, a 4T type, a 5T type, etc. image sensor. The 3T type CMOS image sensor consists of one photodiode and three transistors. The 4T type CMOS image sensor consists of one photodiode and four transistors.

An equivalent circuit and layout of a unit pixel of the 3T type CMOS image sensor are explained as follows.

FIG. 1 is a diagram of an equivalent circuit of a related art 3T type CMOS image sensor, and FIG. 2 is a layout of a unit pixel of a related art 3T type CMOS image sensor.

Referring to FIG. 1, a unit pixel of a related art 3T type CMOS image sensor consists of one photodiode PD and three NMOS transistors T1, T2 and T3. A cathode of the photodiode PD is connected to a drain of the first NMOS transistor T1 and a gate of the second NMOS transistor T2. Sources of the first and second NMOS transistors T1 and T2 are connected to a power line supplying a reference voltage VR. A gate of the first NMOS transistor T1 is connected to a reset line supplying a reset signal RST. A source of the third NMOS transistor T3 is connected to a drain of the second NMOS transistor T2. A drain of the third NMOS transistor T3 is connected to a read circuit via a signal line. A gate of the third NMOS transistor T3 is connected to a row select line supplying a select signal SLCT. The first to third NMOS transistors T1, T2 and T3 are named a reset transistor Rx, a drive transistor Dx and a select transistor Sx, respectively.

An active area 10, as shown in FIG. 2, is defined in a unit pixel of the related art 3T type CMOS image sensor. One photodiode (PD) 20 is formed on a wide region of the active area 10 and three gate electrodes 30, 40 and 50 are overlapped with the rest of the active area 10.

The gate electrode 30 configures a reset transistor Rx. The gate electrode 40 configures a drive transistor Dx. The gate electrode 50 configures a select transistor Sx. The active area 10 of each of the transistors, except the portion overlapped with the corresponding transistor, is doped with impurity ions to become source/drain regions of each of the transistors.

A power voltage Vdd may be applied to the source/drain regions between the reset and drive transistors Rx and Dx, and the source/drain region of the select transistor Sx is connected to a read circuit.

Moreover, the gate electrodes 30, 40 and 50 are connected to signal lines (not shown), respectively. A pad is provided to each of the signal lines to connect to an external drive circuit.

An image sensor and method of forming a microlens thereof according to a related art are explained with reference to the attached drawings as follows.

FIG. 3 is a cross-sectional diagram of an image sensor according to a related art.

Referring to FIG. 3, an image sensor according to a related art consists of a sublayer 11 having photodiode areas and metal lines, an insulating interlayer 12 formed on the sublayer 11, an R/G/B color filter layer 13 formed on the insulating interlayer 12 to transmit a light of a specific wavelength, a planarizing layer 14 on the color filter layer 13 and a microlens 15 formed on the planarizing layer 14 overlapped with the color filter layer 13 to have a prescribed convex curvature to condense light to the photodiode area.

An optical shield layer (not shown) may be provided within the insulating interlayer 12 to prevent light from entering a portion except the photodiode area.

Alternatively, a photogate can be adopted as a photosensing device instead of a photodiode.

The color filter layer 13 consists of color filters of R (red), G (green) and B (blue). Each of the color filters is formed by coating a corresponding photoresist and by performing exposure and development on the coated photoresist using separate masks for each of the color filters.

A curvature and height of the microlens 15 are determined by considering various factors such as a focus of a condensed light. The microlens 15 is formed by coating, patterning and reflowing a photoresist.

In fabricating the related art image sensor, since resolution depends on the number of photodiodes existing in the sublayer 11 to receive an image, a unit pixel size is further reduced according to the progress towards high pixel implementation and pixel size reduction.

According to the size reduction and the microscopic unit pixel, an input of an external image is condensed to the sublayer 11 using an object lens. The object lens includes the microlens 15.

The color filter layer 13 may be classified into a primary color type color filter layer or a complementary color type color filter layer. In case of the primary color type color filter layer, an R/G/B color filter layer is formed. In case of the complementary color type color filter layer, a cyan/yellow/magenta color filter layer is formed. The color filer layer 13 is formed by on-chip technology to enable color separation for color reproduction. The color filter layer 13 is formed of an organic substance. After formation of the color filter layer 13, the planarizing layer 14 is formed on the color filter layer 13 to enable uniformity of the microlens 15 that will be formed over the color filter layer 13.

The planarizing layer 14 may be hardened by a curing process. The curing process is carried out in a hot plate. As a process temperature of the curing process is at least 200° C. or above, a physical property of a surface of the planarizing layer 14 varies because of a solvent that exists during the curing process, which takes place in a sealed convection type oven. Hence, a flowability of the microlens 15 that will be formed on the planarizing layer 14 is varied. Thus, if the flowing property of the microlens 15 is varied, a uniformity of the microlens 15 becomes irregular. The irregularity causes a loss of light.

FIG. 4 is a schematic cross-sectional diagram of a microlens of an image sensor according to a related art.

Referring to FIG. 4, the metal lines within the layer 10 form an optical shield layer and condense light by refracting the light. The light enters a unit pixel and is incident on an upper part of the optical shield layer and the microlens 15. In the related art image sensor shown in FIG. 4, as the microlenses 15 are grown, they differ from each other in being attached to each other or in being spaced apart from each other. Hence, uniformity of an image is degraded. As the microlens 15 is affected by the color filter layer 13, information of a neighbor color filter layer is inputted to the microlens 15. Hence, color reproducibility and color contrast ratio are degraded. Moreover, it is difficult to form a fine pattern due to the reduced photo-resolution caused by mixed pigments in forming the color filter layer 13. It is mandatory to form an upper planarizing layer that overlaps an area between the color filter layers 13 or for forming a space.

However, the related art image sensor and fabricating method thereof have the following problem. After completion of the color filter layer for color separation, the planarizing layer is formed so that the surface of the microlens that will be formed over the color filter layer may be uniform. The planarizing layer is hardened by the curing process. Since the curing process is carried out in the hot plate at the temperature of 200° C. or above, and because of a solvent that exists during the curing process, which takes place in a sealed convection type oven, the flowability of the microlens that will be formed on the planarizing layer varies. Thus, if the flowing property of the microlens varies, the microlens is not formed to be uniform and is irregular. This causes a loss of light.

### SUMMARY OF THE INVENTION

Accordingly, the present invention is directed to an image sensor and fabricating method thereof that substantially obviate one or more problems due to limitations and disadvantages of the related art.

An advantage of the present invention is to provide an image sensor and fabricating method thereof, by which total photoelectric conversion is enabled without light loss by enhancing surface uniformity of a microlens in each area of the microlens.

Additional features and advantages of the invention will be set forth in the description which follows, and will be apparent from the description, or may be learned by practice of the invention. The objectives and other advantages of the invention may be realized and attained by the structure and method particularly pointed out in the written description and claims hereof as well as the appended drawings.

To achieve these and other advantages and in accordance with the purpose of the invention, as embodied and broadly described, an image sensor includes a substrate having a pad area and a cell area, a sublayer on the substrate, the sublayer including a photodiode, a thin film transistor and metal lines, a first planarizing layer on the sublayer, color separating layers on the first planarizing layer aligned with the cell area, a second planarizing layer on at least one of the color separating layers, microlenses on the second planarizing layer, wherein each of the microlenses overlaps one or more of the color separating layers, and a capping layer on the second planarizing layer to fill a gap between adjacent microlenses.

In another aspect of the present invention, a method of fabricating an image sensor includes the steps of forming a sublayer including a photodiode, a thin film transistor and metal lines on a substrate including a pad area and a cell area, forming a first planarizing layer on the sublayer, forming a plurality of color separating layers on the first planarizing layer to align with the cell area, forming a second planarizing layer on the first planarizing layer including at least one of the plurality of color separating layers in the cell area, forming a plurality of microlenses on the second planarizing layer, wherein each of the plurality of microlenses overlaps one or more of the plurality of color separating layers; and forming a capping layer on the second planarizing layer to fill gaps between adjacent microlenses of the plurality of microlenses.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention. In the drawings:

FIG. 1 is a diagram of an equivalent circuit of a related art 3T type CMOS image sensor;

FIG. 2 is a layout of a unit pixel of a related art 3T type CMOS image sensor;

FIG. 3 is a cross-sectional diagram of an image sensor according to a related art;

FIG. 4 is a schematic cross-sectional diagram of a microlens of an image sensor according to a related art;

FIG. 5 is a schematic cross-sectional diagram of a microlens and a planarizing layer of an image sensor according to the present invention;

FIG. 6 is a cross-sectional diagram of an image sensor according to the present invention;

FIG. 7 is a cross-sectional diagram of a pad of an image sensor according to the present invention; and

FIGS. 8A to 8H are cross-sectional diagrams of an image sensor fabricated by a method according to the present invention.

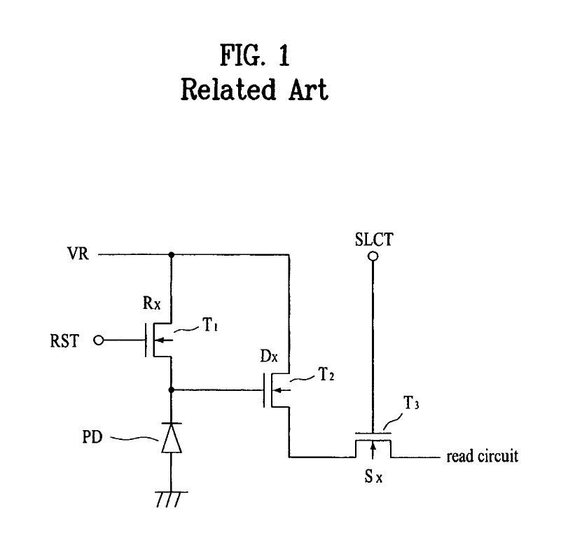

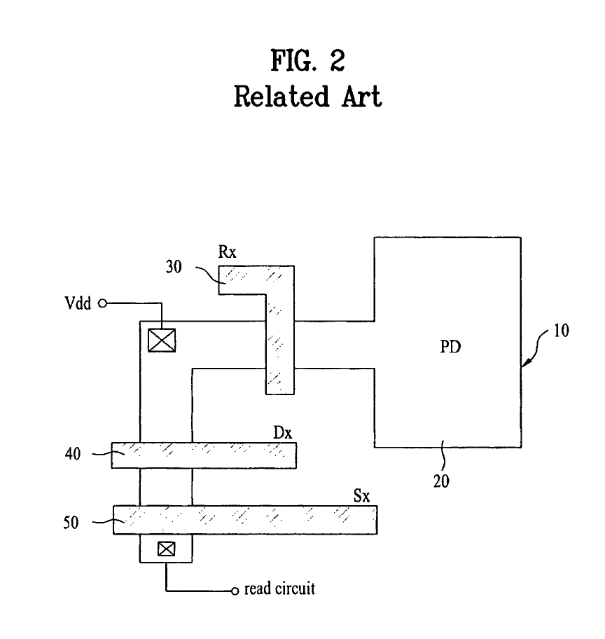

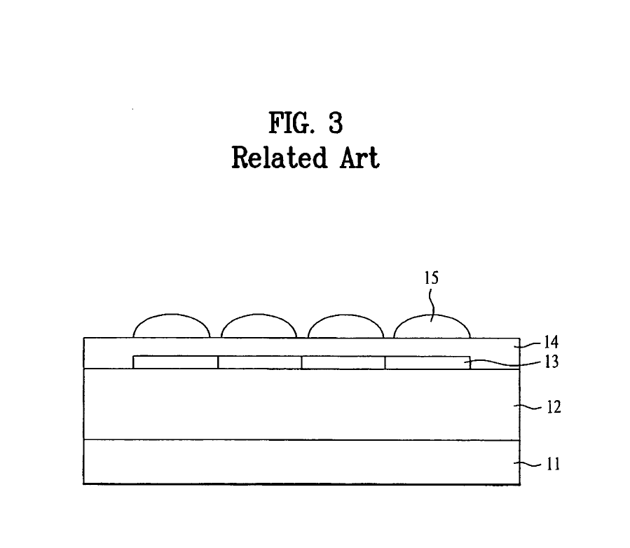

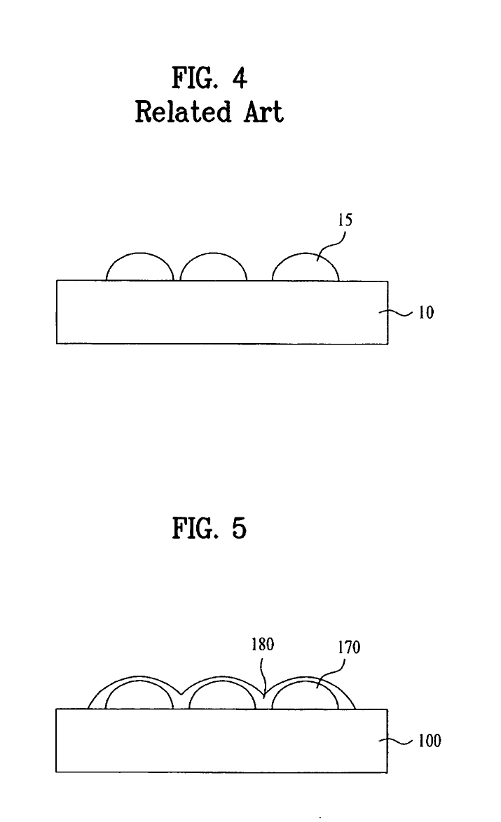

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or similar parts.

FIG. 5 is a schematic cross-sectional diagram of a microlens and a planarizing layer of an image sensor according to the present invention.

Referring to FIG. 5, each gap between microlenses 170, formed on a substrate 100, that are spaced apart from each other is filled with a capping layer 180. This increases a substantial lower area of an object lens, including a microlens and the capping layer, and enables a uniform size and surface curvature in the object lens. Even if UV bleaching is performed on a planarizing layer including the capping layer 180, a microbridge phenomenon, in which microlenses are attached to each other or are unevenly spaced apart from each other, can be prevented.

An image sensor according to the present invention is explained with reference to a pad and a cell of the image sensor as follows.

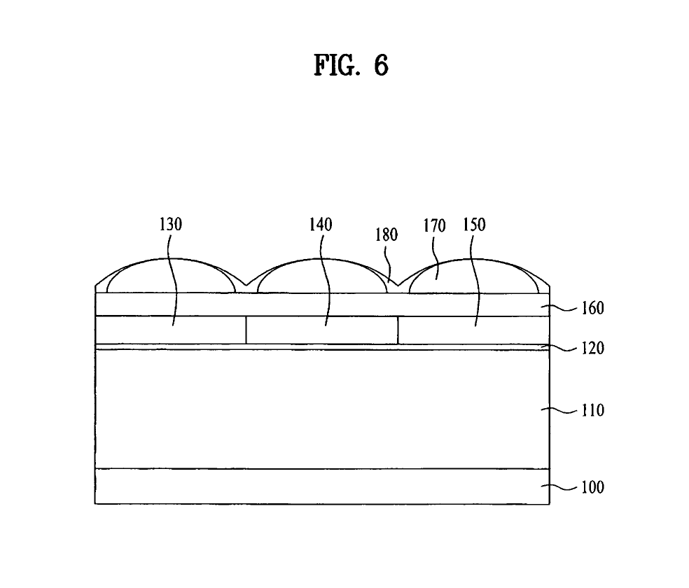

FIG. 6 is a cross-sectional diagram of an image sensor according to the present invention and FIG. 7 is a cross-sectional diagram of a pad of an image sensor according to the present invention.

Referring to FIG. 6, an image sensor includes a substrate 100 having a cell area and a pad area, a sublayer including a photodiode, a plurality of thin film transistors and metal lines, a thin first planarizing layer 120 on the sublayer 110, first to third color separating layers 130, 140 and 150 formed on the first planarizing layer 120 in the cell area, a second planarizing layer 160 on the first to third color separating layer 130, 140 and 150, microlenses 170 on the second planarizing layer 160 that have curved surfaces and that overlap the color separating layers 130, 140 and 150, respectively, and a thin capping layer 180 on the second planarizing layer 160 to fill gaps between the microlenses 170.

Each of the first planarizing layer 120 and the capping layer 180 may be formed to have a thickness of about 20 nm to 50 nm. Also, each of the first planarizing layer 120 and the capping layer 180 may be made of a thermo-hardening resin or a photoresist. The first planarizing layer 120 is formed to maintain planarity of the sublayer 110 and the capping layer 180 is formed to fill the gaps between the microlenses 170. Since the first planarizing layer 120 is formed over the pad area, unlike the second planarizing layer 160, the thermo-hardening resin may be used to prevent corrosion of the pad area in performing a process. If the first planarizing layer 120 is formed of the thermo-hardening resin, a thermo-hardening process is performed to enhance adhesion to the sublayer 110.

Referring to FIG. 7, structures 105 are shown. Also, a bonding pad 190 is blocked by a photoresist component formed to have a thickness of about 60 nm. The bonding pad 190 configures the first planarizing layer 120 and the capping layer 180 like the cell area. In performing a wire bonding process on the pad 190, the capping layer 180 and the first planarizing layer 120 over the pad 190 may be etched back using O₂ plasma to expose the pad 190. After the dry etch-back process, an upper surface of the pad 190 is open. There is no gap as the capping layer 180 still remains between the microlenses 170 in the cell. However, the capping layer does not exist on the microlenses 170. That is, since the capping layer 180 remains between the microlenses 170 after the dry etch-back process, the microlens 170 and the capping layer 180 can play a role as an object lens together. Hence, a bottom area of the object lens is maximized to enable good condensing characteristics of the object lens.

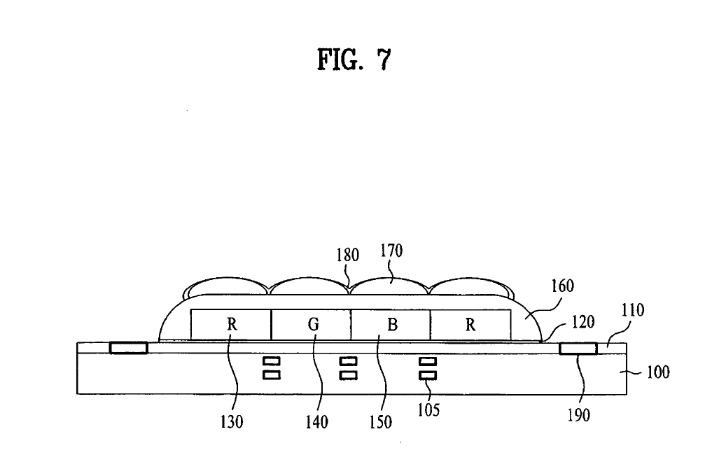

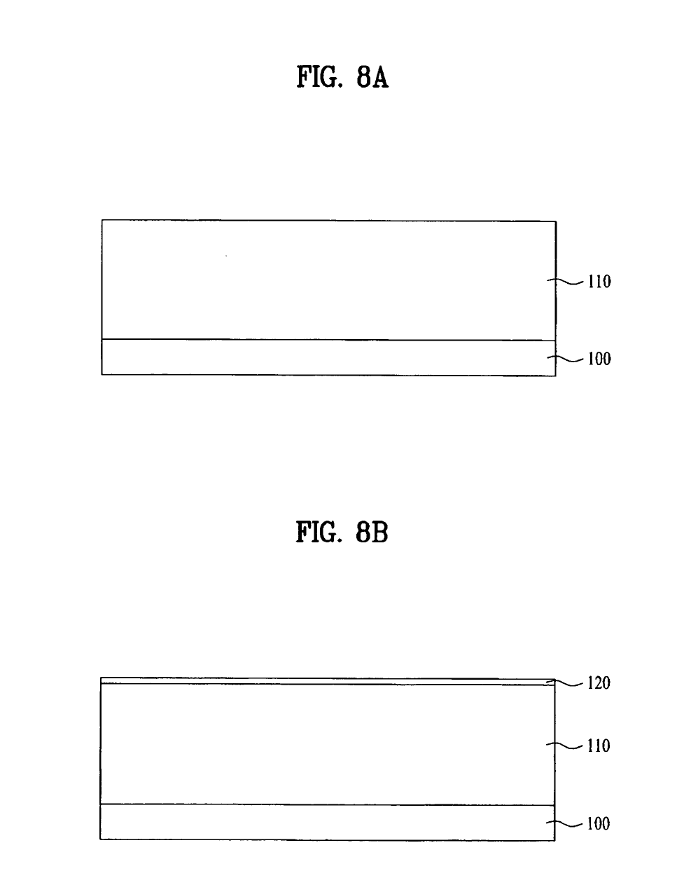

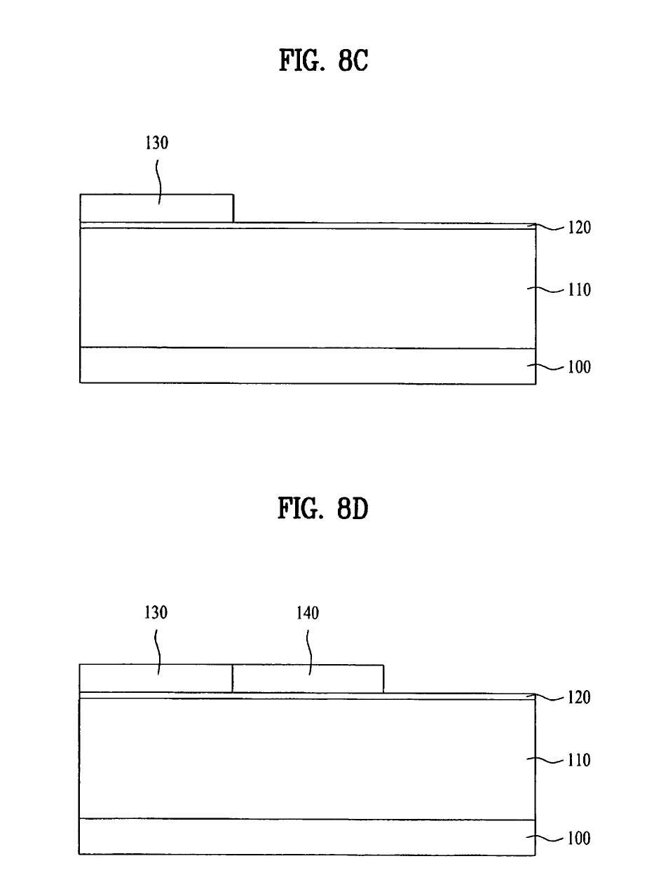

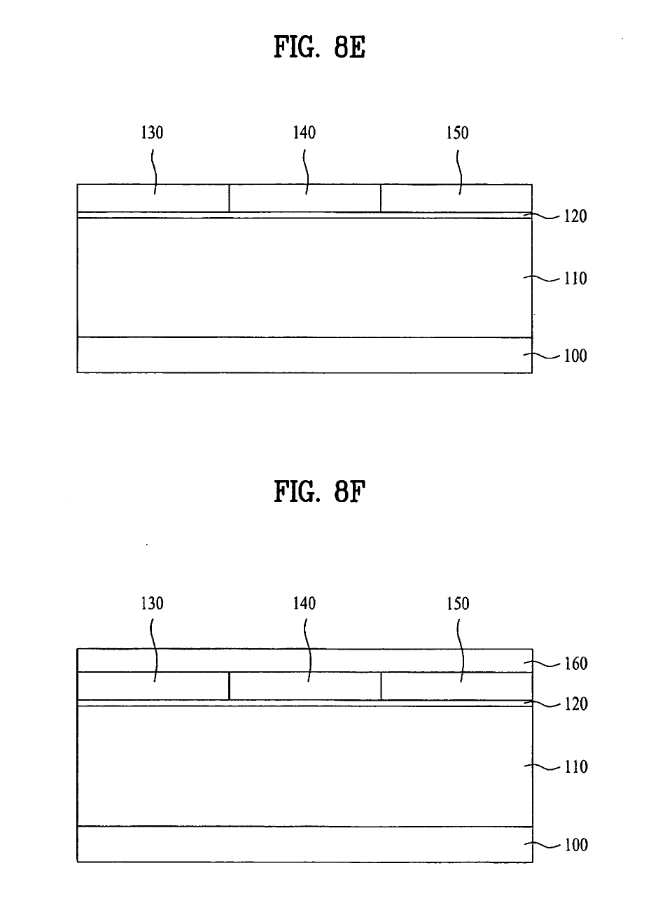

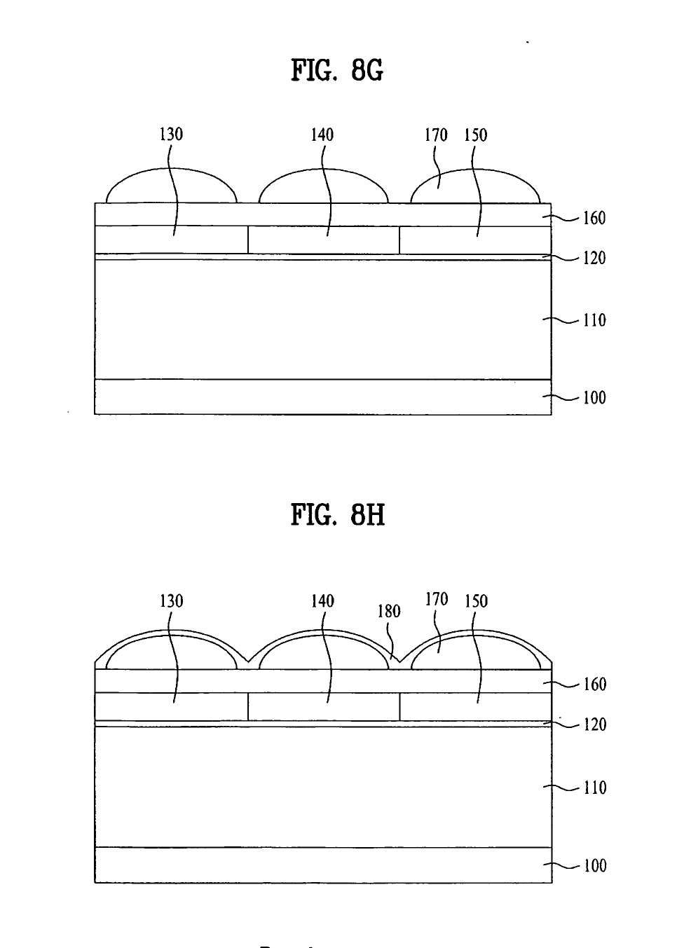

FIGS. 8A to 8H are cross-sectional diagrams of an image sensor fabricated by a method according to the present invention.

Referring to FIG. 8A, a sublayer 110 including a photodiode, a plurality of thin film transistors and metal lines is formed on a substrate 100.

Referring to FIG. 8B, a first planarizing layer 120 is formed of an organic photoresist or a thermo-hardening resin on the sublayer 100. The first planarizing layer 120 may be formed by coating a film to the thickness of about 10 nm to 50 nm and by performing a hard-curing process on the coated film. If the hardening process is thermally performed, the first planarizing layer 120 is formed of the thermo-hardening resin.

The first planarizing layer 120 is formed of an organic substance having good transparency in a visible wavelength range to enhance profile and uniformity of a subsequently formed color filter layer.

Referring to FIG. 8C, a first color separating layer 130 of a first color is formed on the first planarizing layer 120 to overlap a photodiode and to leave a uniform interval in-between photodiodes. The first color separating layer 130 is formed by coating a photoresist that can transmit a light of the first color on the first planarizing layer 120 and by selectively removing the photoresist by exposure and development.

Referring to FIG. 8D, a second color separating layer 140 is formed on the first planarizing layer 120 in an area in which the first color separating layer 130 is not formed. The second color separating layer 140 is formed by coating a photoresist that can transmit a light of the second color on the first planarizing layer 120 and by selectively leaving a portion of the photoresist by exposure and development.

Referring to FIG. 8E, a third color separating layer 150 is formed on the first planarizing layer 120 in an area in which the first color separating layer 130 and the second color separating layer 140 are not formed. The third color separating layer 150 is formed by coating a photoresist that can transmit a light of the third color on the first planarizing layer 120 and by selectively leaving a portion of the photoresist by exposure and development.

The first to third color separating layers 130, 140 and 150 configure a primary color type red/green/blue color filter or a complementary color type cyan/yellow/magenta color filter.

Referring to FIG. 8F, a second planarizing layer 160 is formed to have a thickness of about 0.5 μm to 1.5 μm on the first planarizing layer 120 including the first to third color separating layers 130, 140 and 150. The second planarizing layer 160 is formed to secure a focal length adjustment over the first to third color separating layers 130, 140 and 150 and to secure the uniformity of a subsequently formed microlens. The second planarizing layer 160, which is formed on the first to third color separating layers 130, 140 and 150 only, is provided to the cell area of the substrate and not to the pad area of the substrate.

Referring to FIG. 8G, a photoresist is coated on the second planarizing layer 160. Microlens patterns are formed on the first to third color separating layers 130, 140 and 150, respectively by performing exposure and development on the photoresist. To enhance light transmittance, flood exposure is performed to bleach a basic component of polyaluminium chloride existing within the photoresist. A thermal flow process may then be performed to form a microlens 170 having a specific surface curvature.

The microlens 170 is provided to condense an external light. The microlenses 170 are formed to correspond to the number of pixels of the image sensor. To raise photosensitivity, a size of the microlens 170 is increased. Hence, incident light can be more condensed to the photodiode.

For uniform formations of the microlenses 170, a gap between the microlenses 170 is set to about 0.5 μm to enhance uniformity within an image area.

Referring to FIG. 8H, a capping layer 180 is formed to have a thickness of about 20 nm to 50 nm on the second planarizing layer 160 including the microlenses 170 to fill the gaps between the microlenses 170. The capping layer 180 may be formed of a photoresist having a good transmittance for the same visible wavelength range as the photoresist of the first planarizing layer 120.

Subsequently, a dry ashing process is performed on the capping layer 180 using O₂ plasma to expose upper surfaces of the microlenses 170. The dry ashing process is performed using a separate photosensitive mask. After the dry ashing process, the photosensitive mask is removed using a thinner or an alkali developing solution.

Accordingly, the present invention provides the following effects.

The gap between the microlenses can be filled with the capping layer to increase the lower area of the object lens. Hence, light transmittance is raised to enhance the photosensitivity of the CMOS image sensor. Since the gap between the microlenses is eliminated, the uniformity of the microlenses can be enhanced. Hence, color reproducibility is enhanced to implement the image sensor having a high-level color filter function.

Also, since an aluminum based bonding metal is covered with the thermo-hardening resin, which has good adhesion and protection in the pad area, a pad corrosion due to anodic oxidation and galvanic corrosion can be prevented in forming the color separating layers. Hence, a pad wiring process can be smoothly performed to enhance product reliability.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An image sensor comprising:
a substrate having a pad area and a cell area;
a sublayer on the substrate, the sublayer including a photodiode, a thin film transistor and metal lines;
a first planarizing layer on the sublayer;
color separating layers on the first planarizing layer aligned with the cell area;
a second planarizing layer on at least one of the color separating layers;
microlenses on the second planarizing layer, wherein each of the microlenses overlaps one or more of the color separating layers; and
a capping layer on the second planarizing layer to fill a gap between adjacent microlenses.

2. The image sensor of claim 1, wherein the first planarizing layer comprises a photoresist.

3. The image sensor of claim 1, wherein the capping layer comprises a photoresist.

4. The image sensor of claim 1, wherein the first planarizing layer comprises a thermo-hardening resin.

5. The image sensor of claim 1, wherein the capping layer comprises a thermo-hardening resin.

6. The image sensor of claim 1, wherein a total thickness of the first planarizing layer and the capping layer is about 20 nm to 50 nm.

7. The image sensor of claim 1, wherein a thickness of the second planarizing layer is about 0.5 μm to 1.5 μm.

8. The image sensor of claim 1, wherein the second planarizing layer is formed on all of the color separating layers.

9. A method of fabricating an image sensor, comprising the steps of:
forming a sublayer including a photodiode, a thin film transistor and metal lines on a substrate including a pad area and a cell area;
forming a first planarizing layer on the sublayer;
forming a plurality of color separating layers on the first planarizing layer to align with the cell area;
forming a second planarizing layer on the first planarizing layer including at least one of the plurality of color separating layers in the cell area;
forming a plurality of microlenses on the second planarizing layer, wherein each of the plurality of microlenses overlaps one or more of the plurality of color separating layers; and
forming a capping layer on the second planarizing layer to fill gaps between adjacent microlenses of the plurality of microlenses.

10. The method of claim 9, wherein the step of forming the capping layer on the second planarizing layer includes forming the capping layer on the first planarizing layer in the pad area.

11. The method of claim 10, further comprising the step of removing the capping layer on the plurality of microlenses and in the pad area.

12. The method of claim 11, further comprising the step of removing the first planarizing layer from the pad area.

13. The method of claim 12, wherein the first planarizing layer and the capping layer are removed by a dry etch process using O₂ plasma.

14. The method of claim 9, wherein a thickness of the first planarizing layer is about 20 nm to 50 nm.

15. The method of claim 9, further comprising a step of performing a thermo-hardening process after forming the first planarizing layer.

16. The method of claim 9, wherein a thickness of the capping layer is about 20 nm to 50 nm.

17. The method of claim 9, wherein the step of forming a plurality of microlenses includes the steps of:
forming a photoresist on the second planarizing layer;
forming a photoresist pattern by selectively exposing and developing the photoresist;
bleaching the photoresist pattern by flood exposure; and
forming a curved surface in the photoresist pattern by a thermal flow process.

18. The method of claim 9, wherein the step of forming a second planarizing layer on the first planarizing layer includes forming the second planarizing layer on all of the plurality of color separating layers.
